(19) United States
(12) Patent Application Publication
(10) Pub. No.: US 2008/0220619 A1
(43) Pub. Date: Sep. 11, 2008

(54) METHOD FOR INCREASING MECHANICAL STRENGTH OF DIELECTRIC FILM BY USING SEQUENTIAL COMBINATION OF TWO TYPES OF UV IRRADIATION

(75) Inventors: Kiyohiro MATSUSHITA, Tama (JP); Naoto TSUJI, Tama (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/684,524

(22) Filed: Mar. 9, 2007

(51) Int. Cl. H01L 21/00

(52) U.S. Cl. 438/795; 257/E21.001

(57) ABSTRACT

A method for increasing mechanical strength of a dielectric film includes: providing an initial dielectric film containing porogen; irradiating the initial dielectric film with first UV light having a first wavelength which is substantially or nearly similar to a maximum light absorption wavelength of the porogen for removing the porogen; and then irradiating the porogen-removed dielectric film with second UV light having a second wavelength which is shorter than the first wavelength, thereby increasing mechanical strength of the dielectric film.

### BACKGROUND OF THE INVENTION

1. Field of the Invention

The present invention generally relates to a UV processing of a low-k (low dielectric constant) film, particularly to a method for increasing mechanical strength of a low-k film by using UV irradiation.

2. Description of the Related Art

Reduction of interlayer volumes is essential in meeting the needs for increasing the processing speed, while reducing the power consumption, of highly integrated devices of recent years that adopt increasingly finer wiring designs and multilayer wiring structures. One way to reduce interlayer volumes is to use a low-k (low dielectric constant) film material constituted by a SiO film containing hydrocarbon groups such as methyl groups. Even when a low-k material is used, however, the dielectric constant can only be reduced to around 2.6. To lower the dielectric constant further, the process of forming voids in the film using porogen is drawing the attention as a promising technology. Under this technology, a void-forming hydrocarbon porogen material is introduced into the film in the film formation stage, after which the porogen is removed by means of heat processing or UV processing to form voids. This way, a film with a dielectric constant of 2.1 to 2.5 can be obtained. As the method to remove porogen, UV processing is used more commonly than heat processing because the former offers a greater curing effect.

Traditionally, UV processing has been used widely in the reforming of various processing targets using ultraviolet light and also in the production of substances using photochemical reactions. In the case of low-k films whose mechanical strength (indicated by elastic modulus, or EM) drops as the dielectric constant decreases, the film becomes more vulnerable to stress in subsequent processes such as CMP, wire bonding and packaging. To address this problem, low-k materials can be cured by means of UV irradiation to improve their mechanical strength (refer to U.S. Pat. No. 6,759,098 and U.S. Pat. No. 6,296,909 for examples). UV irradiation shrinks and hardens low-k materials, resulting in 50 to 200% higher mechanical strength (EM).

UV curing can remove porogen from low-k films containing porogen, and also improve the mechanical strength of low-k films in general. Also, photo-CVD that uses photochemical reaction has been studied for many years as a method to obtain various thin films based on films formed by thermal CVD and PECVD, while preventing damage from heat and plasma, in order to meet another demand associated with highly integrated devices of recent years.

### SUMMARY OF THE INVENTION

UV curing can be implemented by various types of lamps, including excimer lamps and mercury lamps. With low-k films containing porogen, UV irradiation can enhance the porogen-removing effect and improve the mechanical strength of the film. Removing porogen from the film thoroughly and quickly will normally reduce the dielectric constant of the film. If the UV energy is too high, however, not only the porogen will break down during the curing process, but the basic skeletal components in the film, such as Si—CH3 or Si—O—Si, will also be damaged. Furthermore, substances produced from the porogen decomposition process will bond with Si and remain in the film, thereby preventing the dielectric constant from decreasing effectively. On the other hand, keeping the UV energy low will effectively remove the porogen and lower the dielectric constant, because damage to the basic skeletal components such as Si—CH3 and Si—O—Si is kept to a minimum when the porogen is decomposed, thus allowing the porogen to be removed without decomposition products remaining in the film. However, such a low level of UV irradiation will reduce the improvement of mechanical strength of the resulting film, and the cure time will also increase.

In particular, Xe excimer lamps and other lamps emitting DUV light are known to have short wavelengths and provide a high curing effect, and these lamps are associated with a significant production of substitution groups such as Si—H and Si—OH. The production of these substitution groups is considered the reason why the film has higher hygroscopicity and consequently becomes unstable with changing stress and dielectric constant levels. On the other hand, high-pressure mercury lamps and other UV lamps with relatively long wavelengths keep the production of these substitution groups to a minimum. However, the curing speed is much lower compared to Xe excimer lamps emitting DUV light.

In view of the above, one embodiment of the present invention solves these problems by achieving a film offering both low dielectric constant and high strength through combination of one type of UV light suitable for porogen removal and dielectric constant reduction, with another type of UV light suitable for improvement of mechanical strength.

The above is explained in greater details. In general, hydrocarbons (CHx) are used as porogens. On the other hand, high-energy UV light causes Si—CH3 to detach and thus produces Si—H and Si—OH. Since the basic Si—O—Si skeletal structure is also partially broken, if a porogen is present the substances produced by UV-decomposition of the porogen will also bond with Si, just like H and OH do, and remain in the film. When an excimer lamp is used to implement curing in a single process, two phenomena will occur as mentioned above-namely, production of Si—H and Si—OH, and remaining in the film of decomposition products bonded with Si. As a result, the curing efficiency and effect will drop. This problem of lower curing efficiency and effect can be resolved by using a two-step UV irradiation process, in which one type of UV light that causes minimal damage to Si—CH3 and Si—O—Si bonds is used to remove porogen, and then a high-energy excimer lamp is used to cure the film to enhance its strength. Since porogen is almost entirely removed before high-energy UV light is irradiated, there is no longer a need to remove porogen in the high-energy UV irradiation process. In other words, the curing effect of the excimer lamp is used only toward improving the film strength, which allows the target strength to be achieved more quickly than when only an excimer lamp is used for curing. Consequently, Si—H and Si—OH contents can be reduced efficiently. Here, it should be noted that the aforementioned explanation of phenomena applies only to certain embodiments of the present invention, but not all embodiments, and that its application to all embodiments is not intended.

For purposes of summarizing the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic diagram of a plasma CVD apparatus useable in an embodiment of the present invention.

FIG. 2 is a schematic diagram of a UV irradiation apparatus usable in an embodiment of the present invention.

FIG. 3 is a schematic diagram of a cluster type apparatus including a reaction chamber and two UV irradiation chambers usable in an embodiment of the present invention.

FIG. 4 is a graph showing the relationship between dielectric constant and cure time according to an embodiment of the present invention.

FIG. 5 is a graph showing the relationship between elastic modulus and cure time according to an embodiment of the present invention.

FIG. 6 is a graph showing the relationship between refractive index and cure time according to an embodiment of the present invention.

### DETAILED DESCRIPTION OF THE PREFERRED EMBODIMENT

The present invention will be explained with respect to preferred embodiments. However, the preferred embodiments are not intended to limit the present invention.

In an embodiment, the present invention provides a method for increasing mechanical strength of a dielectric film, comprising the steps of: (i) providing an initial dielectric film containing porogen; (ii) irradiating the initial dielectric film with first UV light having a first wavelength which is substantially or nearly similar to a maximum light absorption wavelength of the porogen for removing the porogen; and then (iii) irradiating the porogen-removed dielectric film with second UV light having a second wavelength which is shorter than the first wavelength, thereby increasing mechanical strength of the dielectric film.

The above embodiment includes, but is not limited to, the following embodiments. Each embodiment can be combined, and the elements in each embodiment can be interchangeably or additionally used in another embodiment.

In an embodiment, the first wavelength may be in the range of 200 nm to 300 nm. The second wavelength may be 200 nm or lower. In an embodiment, the fist UV light may be light emitted from a high-pressure mercury lamp, and the second UV light may be emitted from an Xenon excimer lamp.

In an embodiment, the porogen may be a pore-generating precursor gas containing C and H. The porogen may be a hydrocarbon-containing gas.

In an embodiment, the step of irradiation of the first UV light may continue until a refractive index of the initial dielectric film reaches substantially or nearly a minimum value, and then the step of irradiation of the second UV light may start. In an embodiment, the method may further comprise determining an irradiation time of the first UV light based on a refractive index of a dielectric film equivalent to the initial dielectric film, wherein the irradiation time is such that the refractive index reaches substantially or nearly a minimum value.

In an embodiment, the initial dielectric film may have an initial dielectric constant (e.g., 2.6-3.0), the porogen removed dielectric film (upon the end of the step) may have a first dielectric constant (e.g., 2.0-2.6), and the mechanical strength increased dielectric film (upon the end of the step) may have a second dielectric film (e.g., 2.0-2.6), wherein the first dielectric constant is at least 10% lower (including 15% lower, 20% lower, and values between any two numbers of the foregoing) than the initial dielectric constant, and the second dielectric constant is nearly the same as the first dielectric constant.

In an embodiment, the initial dielectric film except the porogen may be constituted by Si, C, O, and H. The initial dielectric film may have a thickness of 100 nm to 500 nm (including 200 nm, 300 nm, 400 nm, and values between any two numbers of the foregoing). The initial dielectric film may have an elastic modulus of 3 GPa to 4 GPa, and the mechanical strength-increased dielectric film has an elastic modulus of 5 GPa or higher. The step of providing the initial dielectric film may comprise forming the initial dielectric film on a substrate by plasma CVD.

Further embodiments will be explained below.

In an embodiment, the initial dielectric film contains Si—CH₃ bonds and Si—O—Si bonds which form a main matrix of the film and includes the porogen which is a pore-generating precursor material. The initial dielectric film may be formed on a substrate at a susceptor temperature to 0-350° C. in a 1-30 Torr atmosphere by, for example, plasma CVD which may be conducted by applying 13.56-60 MHz RF power. At that time, molecules, which serve as a porogen substance for pore formation, are taken into a film. After that, when pores are formed after the porogen substance being included in the film is decomposed and come out from the film by a UV curing process, unstable bonds are also removed, and thus the film's mechanical strength is improved substantially.

In an embodiment, the porogen substance may be hydrocarbon gas, alcohol gas, or aliphatic ether gas or any one or any combination of CₙH₂ₙ₊₂, CₙH₂ₙ, and CₙH₂ₙ₊₂O wherein n is an integer of 1-5.

For example, the low-dielectric-constant thin film formed on a substrate placed on a susceptor may have a dielectric constant of about 2.6 or higher (including 2.7, 2.8, 2.9, 3.0, and values between any two numbers of the foregoing) and an elastic modulus of about 4.5 GPa or less (including 4 GPa, 3 GPa, 2 GPa, 1 GPa, and values between any two numbers of the foregoing). The film may be formed by plasma CVD using an organosilicon gas and an additive gas at a susceptor temperature of lower than 350° C. (including 300° C., 250° C., 200° C., 150° C., 100° C., 50° C., 0C, −10° C., and values between any two numbers of the foregoing).

The organosilicon gas may have a general formula SiₐO_{b}CₓH_{y} wherein, a, b, x, and y are arbitrary integers. Further, the organosilicon may be any one or any combination of dimethyldimethoxylsilane (DMDMOS), diethyldimethoxysilane (DEDMOS), phenyltrimethoxysilane (PTMOS), 1,3-dimethoxytetramethyldisiloxane (DMOTMDS), hexamethyldisilane (HMDS), divinyldimethylsilane (DVDMS), tetramethylsilane (4MS), diethylmethylsilane dimethylsilane(DEMS), and octamethylcyclotrisiloxane (OMCTS).

The organosilicon compounds and the film formation disclosed in U.S. Pat. No. 6,455,445, U.S. Pat. No. 6,818,570, United States Patent Publication No. 2004/0038514 A1, and U.S. patent application Ser. No. 11/175,511 owned by the same assignee as in this application can be used in the present invention, the disclosure of which is incorporated herein by reference in their entirety.

In an embodiment, the porogen gas may be any one or any combination of CₙH₂ₙ₊₂, CₙH₂ₙ, and CₙH₂ₙ₊₂O wherein n is an integer of 1-5. In another embodiment, the porogen gas may be selected from the group consisting of alcohols and aliphatic ethers which may include both non-cyclic and cyclic compounds. The hydrocarbon gas, alcohol gas, and aliphatic ether gas disclosed in U.S. Pat. No. 6,818,570 can be used in the present invention, the disclosure of which is incorporated herein by reference in its entirety. A flow rate of the porogen gas may be 50-1,500 sccm, preferably 100-900 sccm (including 200 sccm, 300 sccm, 400 sccm, 500 sccm, 600 sccm, 700 sccm, 800 sccm, and values between any two numbers of the foregoing).

An inert gas may be further used for plasma CVD. The inert gas may be any one or any combination of He, Ar, Kr, and Xe. These respective gases have different ionization energy and collision cross sections, a reaction in the vapor phase can be controlled by changing a combination of these gases. A flow rate of the inert gas may be 0-600 sccm, preferably 30-300 sccm (including 50 sccm, 100 sccm, 150 sccm, 200 sccm, 250 sccm, and ranges between any two numbers of the foregoing).

A flow rate of the porogen gas may be no less than that of the organosilicon gas. A ratio of the organosilicon to the porogen gas may be 1:1 to 1:10, typically 1:1.5 to 1:5. In an embodiment, a flow rate of the organosilicon may be 50-500 sccm, a flow rate of the porogen gas may be 50-900 sccm, and a flow rate of the inert gas may be 30-300 sccm.

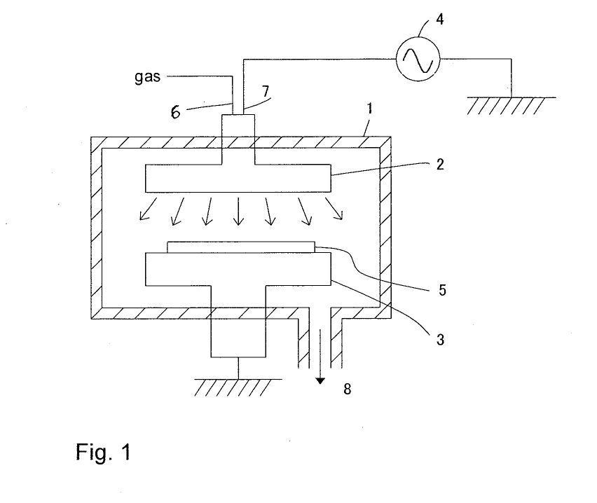

The film formation step of the present invention can be practiced using a plasma CVD apparatus shown in FIG. 1. The plasma CVD apparatus comprises a reactor 1, an upper electrode 2, a lower electrode 3, a gas inlet port 6, and an RF introduction portion 7. The upper electrode 2 and the lower electrode 3 are disposed facing and parallel to each other, and are heated by heaters embedded in them respectively. A semiconductor substrate 5, which is a workpiece, is placed on the lower electrode 3 and is heated and held. On a bottom surface of the upper electrode 2, a number of fine pores are provided, from which a jet of gas is emitted supplied from the gas inlet port 6. RF power is supplied from a RF generator 4; the gas inlet port 6 and the RF introduction portion 7 are electrically isolated. When a film has been formed on a semiconductor substrate, with the semiconductor being held inside the reactor, gases inside the reactor are exhausted from an exhaust port 8, and are replaced by a reducing gas or a mixture gas of a reducing gas and an inert gas.

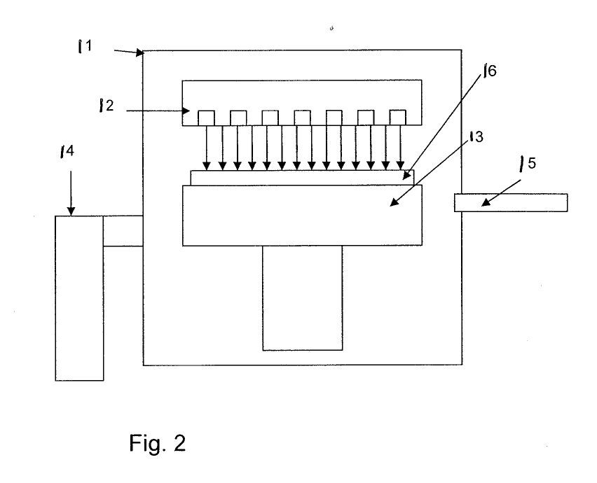

In an embodiment, a low-dielectric-constant structure is formed on a semiconductor workpiece by process gases introduced into the reactor and by plasma generated by RF discharge. This film is nothing but a workpiece before a UV curing process is performed. Subsequently, by performing the curing process using a UV cure apparatus shown in FIG. 2, a low-dielectric-constant film which is a silicon-containing hydrocarbon compound having a dielectric constant of 2.0-2.6 (including 2.1, 2.2, 2.3, 2.4, 2.5, and values between any two numbers of the foregoing) can be ultimately formed.

In an embodiment, subsequently, a curing process is performed on the semiconductor substrate 16 taken out from the reactor using the UV cure apparatus shown in FIG. 2. The UV cure apparatus comprises a process chamber 11, a UV lamp 12, a susceptor 13, an exhaust port 14, and a gas inlet port 15. The UV lamp 12 and the susceptor 13 are disposed parallel, and are heated by heaters embedded in them respectively. The semiconductor substrate 16, which is a workpiece, is placed on the susceptor 13 and is heated and held. Projected from the UV lamp whose wavelength range may be selected from 100-400 nm, e.g., 172-250 nm, light is irradiated toward the semiconductor substrate 16 via a transmission window (not shown) disposed between the UV lamp 12 and the susceptor 13. When the semiconductor substrate is irradiated, gases such as He, H₂, N₂, CO₂, etc. are being introduced through the gas inlet port 15. As soon as pores are formed in the film by removing the porogen substance (e.g., H, O, C, etc. are desorbed from a low-dielectric-constant structure), unstable bonds no longer exist; hence, a film having a lower dielectric constant and higher mechanical strength can be obtained.

The above-described apparatus comprises the chamber which can control pressure from a vacuum to atmospheric pressure and a UV irradiation unit disposed on the chamber. However, any suitable apparatus which can perform UV irradiation can be used.

As the UV cure apparatus, the apparatus disclosed in U.S. patent application Ser. No. 11/040,863 and Ser. No. 11/155,841 owned by the same assignee as in this application can be used, the disclosure of which is incorporated herein by reference in their entirety.

In an embodiment of the present invention, a sequential combination of two types of UV irradiation are used. The first type of UV irradiation uses UV light designed for effectively removing the porogen and lowering the dielectric constant (e.g., decomposing the porogen molecules but suppressing breaking Si—O bonds and Si—C bonds and suppressing re-bonding decomposed or disassociated substance to Si), and the second type of UV irradiation uses UV light designed for effectively increasing mechanical strength (e.g., removing unstable bonds and restructuring the matrix). The above sequential combination can result in significant synergic effects, e.g., it can bring about high mechanical strength and high curing speed which cannot be achieved based on any single UV irradiation.

In general, porogens are hydrocarbon gases that absorb light having certain wavelengths (200 to 300 nm). Accordingly, in one embodiment of the present invention the first UV light source covering this wavelength range (200 to 300 nm) can be used to effectively remove porogen. Among lamps emitting UV light of 200 to 300 nm in wavelength, mercury lamps are commonly known and these lamps can effectively remove porogen. However, UV light around these wavelengths has low energy, and consequently films cannot be cured efficiently and curing also takes a very long time. On the other hand, short-wavelength light, especially UV light with a wavelength of 200 nm or below called “DUV,” has a high curing effect and is able to cure films over a short period of time. However, high-energy light such as DUV has a strong capability to break chemical bonds. Consequently, porogen is broken down and porogen-derived hydrocarbons will be incorporated into the film structure in the heat-induced recombination process. This inhibits sufficient lowering of dielectric constants.

The mechanical strength of a low-k film can be enhanced by irradiating UV light onto the film to break —CH3 and —Si—O bonds in the film and then allowing them to recombine to build an O—Si—O network. Here, use of two types of UV light can improve the film's mechanical strength, because it allows an O—Si—O network to be built effectively, while suppressing the recombination with Si of porogen molecules and molecules of other decomposition products, as explained above. Any UV lamps can be selected as deemed appropriate in accordance with the type of porogen used, type of applicable low dielectric constant film, and so on. However, mercury lamps and excimer lamps can be used favorably. Excimer lamps include Xe excimer lamps that emit 172-nm DUV light to produce high energy and achieve quick curing. Mercury lamps come in various types that cover a wide lamp pressure range from low pressures to ultrahigh pressures. These lamps produce light with wavelengths of 185 nm, 254 nm and 365 nm, among others.

In both the first and second UV irradiations, the atmosphere in which the substrate is retained is normally substituted by an inactive gas to prevent oxidization of the low-k film. In one embodiment of the present invention, N2, He or Ar is used as this inactive gas and the pressure is adjusted to a range from approx. 0.1 Torr to near atmospheric pressure (including 1 Torr, 10 Torr, 50 Torr, 100 Torr, 1,000 Torr and values between any two numbers of the foregoing, but preferably between 1 Torr and 10 Torr), and in this atmosphere the processing target, or a semiconductor substrate that has been carried in from the substrate loading port via the gate valve, is placed on the heater set to a temperature range of approx. 0 to 650° C. (including 10° C., 50° C., 100° C., 200° C., 300° C., 400° C., 500° C., 600° C. and values between any two numbers of the foregoing, but preferably between 300° C. and 450° C.), after which the substrate is irradiated by the UV emitters from an appropriate distance (between 1 cm and 10 cm).

In one embodiment of the present invention, during the first UV irradiation a type of UV light with a wavelength in a range of approx. 200 nm to approx. 400 nm (including 250 nm, 300 mn, 350 nm and values between any two numbers of the foregoing, but preferably between approx. 200 nm and approx. 300 nm) is irradiated at an output in a range of approx. 10 mW/cm² to approx. 2,000 mW/cm² (including 50 mW/cm², 100 mW/cm², 200 mW/cm², 500 mW/cm², 800 mW/cm², 1,000 mW/cm² and values between any two numbers of the foregoing) onto a thin film formed on a semiconductor substrate, either continuously or in pulses at a frequency in a range of approx. 1 Hz to approx. 1,000 Hz (including 10 Hz, 100 Hz, 200 Hz, 500 Hz and values between any two numbers of the foregoing). A desired frequency can be selected in accordance with the type of porogen used, among others.

In one embodiment of the present invention, during the second UV irradiation a type of UV light with a wavelength in a range of approx. 200 nm or shorter (including 180 nm, 150 nm, 100 nm and values between any two numbers of the foregoing) is irradiated at an output in a range of approx. 1 mW/cm² to approx. 1,000 mW/cm² (including 30 mW/cm², 50 mW/cm², 100 mW/cm², 500 mW/cm² and values between any two numbers of the foregoing) onto a thin film formed on a semiconductor substrate, either continuously or in pulses at a frequency in a range of approx. 1 Hz to approx. 1,000 Hz (including 10 Hz, 100 Hz, 200 Hz, 500 Hz and values between any two numbers of the foregoing). A desired frequency can be selected in accordance with the type of low-k film used, among others. Since the second UV light has higher energy than the first UV light, it can be irradiated at a lower power than the first UV light. In one embodiment of the present invention, the range of irradiation power is from approx. 1/10 to 1/20.

In one embodiment of the present invention, the irradiation time is in a range of approx. 100 sec to approx. 20 min (including 200 sec, 500 sec, 1,000 sec and values between any two numbers of the foregoing) for both the first UV irradiation and second UV irradiation. The first UV irradiation time can be determined by, for example, the relationship between film refractive index (RI) and cure time. In general, the RI of a film decreases as porogen is removed by UV curing and the porogen content in the film decreases. The minimum RI value represents the lowest porogen content. After this point, the RI increases gradually as the film's density increases and hardness rises. A point at which the RI roughly reaches the minimum value can be used as the end point of the first UV irradiation. If used solely for the purpose of porogen removal, the high-energy second UV irradiation can achieve the minimum RI value more quickly than the first UV irradiation. Due to its high energy, however, this UV light promotes breakdown of not only porogen, but also other structures and may cause porogen molecules and molecules of other decomposition products to recombine with Si. For this reason, this light is not suitable for porogen removal. In addition, the second UV irradiation does not reduce the dielectric constant sufficiently. Accordingly, it is better to implement the first UV irradiation at a UV wavelength that causes the RI to reach near its minimum value after 200 seconds or longer. The second UV irradiation is effective in improving the mechanical strength of the porogen-removed film. In the second UV irradiation, the dielectric constant does not drop significantly because porogen has already been removed from the film.

Here, this hybrid process consisting of the first UV irradiation and second UV irradiation allows the irradiation time needed to achieve a certain mechanical strength (such as 4.5 GPa in elastic modulus) to be shortened considerably. For example, the irradiation time can be shortened to one-third (±50%) the time required when the first UV irradiation is used alone, or to one-half (±50%) the time required when the second UV irradiation is used alone.

Although not illustrated as part of the apparatus shown in FIG. 2, an irradiation window is provided to implement uniform UV irradiation. This irradiation window can be made by synthetic quartz, for example, but any material can be used as long as it can isolate the reactor from atmosphere but transmit UV. Multiple tube-shaped UV emitters are laid in parallel inside the UV irradiation unit, and the layout of these emitters is optimized to achieve uniform irradiation. A reflection plate is provided to allow the UV light from each UV emitter to be reflected properly onto the thin film, where the angle of the reflection plate is made adjustable to achieve uniform irradiation. The UV emitters are structured so that they can be easily removed and replaced. Gas is introduced through a flange, while multiple gas inlet ports are provided in a symmetrical pattern to produce a uniform processing atmosphere.

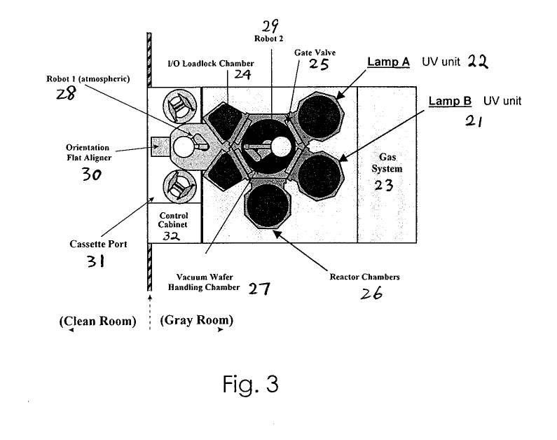

FIG. 3 is a schematic diagram showing one example of the apparatus used to implement the first UV irradiation and second UV irradiation in one embodiment of the present invention. This apparatus forms a low-k film in a reactor chamber 26, after which the substrate is transferred first into a lamp B UV unit 21 via a gate valve 25 using a robot 2 (vacuum robot) in a vacuum wafer handling chamber 27, to undergo UV processing. Next, in a similar manner the substrate is transferred into a lamp A UV unit 22 to undergo UV processing. The processed substrate is transferred into an I/O load-lock chamber 24 and stored into a cassette port 31 by means of a robot 28 (atmospheric robot). An unprocessed substrate is then carried into the load-lock chamber 24 by the robot 28 from the cassette port 31. Here, the substrate placed on the robot 28 is position-corrected by an orientation flat aligner 30. The gas in the reactor chamber is adjusted by a gas system 23, and the transfer into the load-lock chamber 24, transfer out of the load-lock chamber 24 and other movements are controlled by a control unit in a control cabinet 32. This semiconductor manufacturing apparatus implements the aforementioned series of processing in an automatic sequence, where the processing steps include introduction of gas, UV irradiation, stopping of irradiation, and stopping of gas supply.

Here, lamp A may be a Xe excimer lamp while lamp B may be a high-pressure mercury lamp. These lamp units have different structures and are therefore placed in different UV units to perform the respective processing, as explained above. If both lamps are of the same type, such as when both are KrCl excimer lamps (wavelength: 222 nm), it is possible to place both lamps in the same unit.

### EXAMPLES

The present invention is explained below using examples. It should be noted, however, that the present invention is not limited to these examples. In the following examples, the specific values can be changed within a margin of approx. ±50%.

A low-k film was formed using the film forming apparatus illustrated in FIGS. 1 and 3 under the conditions specified below. Here, the film composition used for curing was an uncured low-k film formed in a CVD reactor by adding a porogen to a siloxane precursor.

Material gas: DEMS (diethylmethylsilane)

Flow rate of material gas (DEMS): 0.5 g/min

Porogen gas: ATRP (alpha terpinene)

Flow rate of porogen gas (ATRP): 1 g/min

Other gases: He, O2

Flow rates of other gases (He/O2): 800 sccm/50 sccm

Film forming temperature: 300° C.

Film forming pressure: 1,000 Pa

RF application (wavelength, output): 13.56 MHz, 1,000 W

Film thickness: 500 nm

Next, the film was processed using the UV irradiation apparatus illustrated in FIGS. 2 and 3 under the conditions specified below, in three modes of using lamp B (first UV lamp) only, using lamp A (second UV lamp) only, and using both lamps B and A consecutively.

Lamp B: High-pressure mercury lamp (broadband wavelength range: 200 to 300 nm)

Lamp A: Xenon excimer UV lamp (172 nm, DUV)

Lamp B wattage: 20 kW

Lamp A wattage: 1.5 kW

Distance between lamp B and substrate: 30 cm

Distance between lamp A and substrate: 10 cm

Lamp B processing temperature: 400° C.

Lamp B processing pressure: 5 torr

Lamp B atmosphere (gas type, flow rate): N2, 4 slm

Lamp A processing temperature: 400° C.

Lamp A processing pressure: 5 torr

Lamp A atmosphere (gas type, flow rate): N2, 4 slm

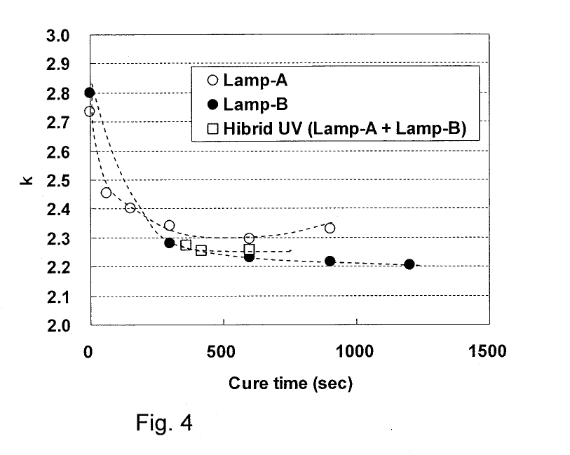

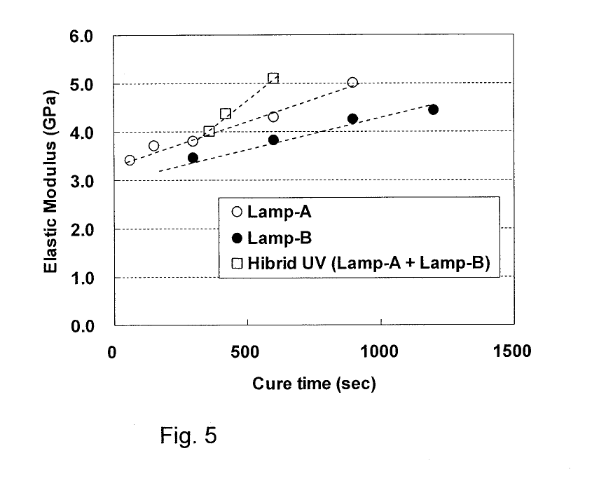

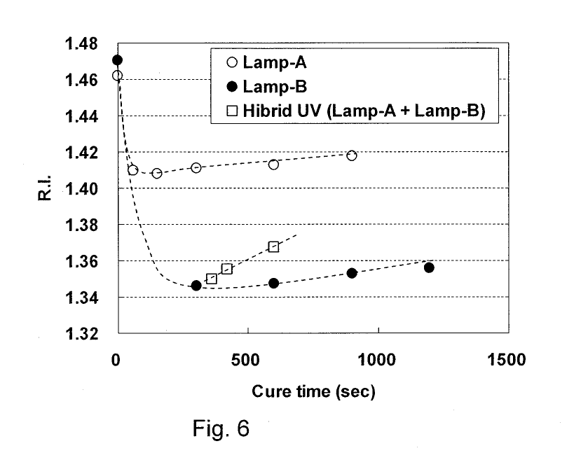

FIG. 4 illustrates the relationship between dielectric constant (k) and cure time, FIG. 5 illustrates the relationship between mechanical strength (elastic modulus) and cure time, and FIG. 6 illustrates the relationship between film refractive index and cure time. All graphs are based on three curing modes: curing with the broadband-wavelength, high-pressure mercury lamp (lamp B) for 300 sec, 600 sec, 900 sec and 1,200 sec; curing with the DUV high-energy excimer lamp (lamp A) for 60 sec, 120 sec, 300 sec, 600 sec and 900 sec; and curing with the high-pressure mercury lamp at wavelengths covering a range from 200 to 300 nm for 300 sec, and then curing with the excimer lamp for additional 60 sec, 120 sec and 300 sec. In the last hybrid mode, the irradiation chamber for the mercury lamp (lamp B) and one for the excimer lamp (lamp A) were incorporated into a single system, as shown in FIG. 3, where the wafer was cured in the lamp B chamber and then transferred into the adjacent lamp A chamber in vacuum to be cured consecutively.

As shown in FIGS. 4 and 5, the high-energy excimer lamp (lamp A) resulted in higher dielectric constants compared to when the broadband lamp (lamp B) was used for curing, and lamp A also resulted in higher elastic moduli. When the film was cured with lamp B for 300 sec, followed by curing with lamp A, the dielectric constant was as low as the level achieved with lamp B only, while the elastic modulus was higher than the level achieved with any single UV irradiation. When the film was cured with lamp B for 300 sec, followed by additional curing with lamp A, the elastic modulus improved more than five times faster than when only lamp B was used for curing.

On the other hand, the relationship between film refractive index (RI) and cure time shown in FIG. 6 indicates presence of minimum RI values. In general, the RI of a film decreases as porogen is removed by UV curing and the porogen content in the film decreases. The minimum RI value represents the lowest porogen content. Thereafter, the RI increases gradually as the film density increases and hardness rises. If removal of porogen is the sole purpose, therefore, it seems a sufficient effect was achieved after around 120 sec with lamp A and after around 300 sec with lamp B.

In general, porogens are hydrocarbon gases that absorb light having certain wavelengths (200 to 300 nm). Therefore, use of UV light covering this wavelength range (200 to 300 nm) can effectively remove porogen. Among lamps that emit UV light having a wavelength range of 200 to 300 nm, mercury lamps are commonly known. Although these lamps are considered effective in removing porogen, however, UV light around these wavelengths (lamp B) has low energy, and consequently films cannot be cured efficiently and curing also takes a very long time. On the other hand, short-wavelength light (lamp A), especially UV light with a wavelength of 200 nm or below called “DUV,” has a high curing effect and is able to cure films over a short period of time. However, high-energy light such as DUV has a strong capability to break chemical bonds. Consequently, porogen is broken down and porogen-derived hydrocarbons will be incorporated into the film structure in the heat-induced recombination process. This is considered the reason why dielectric constants cannot be lowered sufficiently.

Table 1 lists the compositions of films cured with lamp A and lamp B, respectively. As evident from this table, the film cured with lamp A contains large amounts of carbon and hydrogen attached to carbon. Here, these carbon and carbon-attached hydrogen are not due to undecomposed porogen, which has been confirmed by absence of porogen separation in a TDS analysis.

TABLE 1

Composition [atomic %]

| | H | C | O | Si |
|---|---|---|---|---|
| Lamp A | 41.8 | 22.9 | 21.7 | 13.5 |
| 600 sec. | | | | |
| Lamp B | 34.5 | 19.3 | 28.2 | 18.1 |
| 1200 sec. | | | | |

From the above, it is shown that a low-k film offering low dielectric constant and high strength can be achieved by removing the porogen by curing the film using UV lamp B capable of efficiently removing porogen, and then curing the film using UV lamp A capable of efficiently enhancing the mechanical strength of the film. As a guide for desirable cure times for the respective curing processes, in the case of a porogen film ideally the film should be cured with broadband lamp B until the RI reaches the lowest value among all RI values measured before and after curing, and then given additional curing using lamp A. By curing the film until the RI reaches the minimum value, a majority of porogen can be removed. As a result, additional curing with lamp A will not cause porogen to remain in the film.

The present invention includes the above mentioned embodiments and other various embodiments including the following:

1) Irradiate a type of UV light with a wavelength of 200 nm or longer, and then irradiate a different type of UV light with a wavelength shorter than 200 nm.

2) Irradiate a type of UV light with a wavelength of 200 nm or longer to remove substantially or nearly all porogen from the film, and then irradiate a different type of UV light with a wavelength shorter than 200 nm to improve the mechanical strength of the film.

3) Irradiate a type of UV light with a wavelength of 200 nm or longer until the RI reaches substantially or nearly a minimum value, and then irradiate a different type of UV light with a wavelength shorter than 200 nm to improve the mechanical strength of the film.

4) Irradiate a type of UV light with a wavelength near the range where the light absorption by porogen becomes the greatest to eliminate a majority of porogen from the film, and then irradiate a different type of UV light with a wavelength shorter than the aforementioned UV light to improve the mechanical strength of the film.

5) Irradiate a type of UV light with a wavelength near the range where the light absorption by porogen becomes the greatest until the RI reaches substantially or nearly a minimum value, and then irradiate a different type of UV light with a wavelength shorter than the aforementioned UV light to improve the mechanical strength of the film.

6) Provide at least two types of UV light, irradiate one UV light associated with the lower rises in C and H contents in the film until the RI reaches substantially or nearly a minimum value, and then irradiate the other UV light to improve the mechanical strength of the film.

7) Irradiate the first UV light onto a low-k film containing porogen to remove the porogen while also reducing the dielectric constant, and then irradiate the second UV light to improve the mechanical strength of the film without substantially changing the dielectric constant.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A method for increasing mechanical strength of a dielectric film, comprising the steps of:
providing an initial dielectric film containing porogen;
irradiating the initial dielectric film with first UV light having a first wavelength which is substantially or nearly similar to a maximum light absorption wavelength of the porogen for removing the porogen, wherein the irradiation of the first UV light continues until a refractive index of the initial dielectric film reaches substantially or nearly a minimum value, the irradiation of the first UV light being such that the refractive index reaches substantially or nearly the minimum value at least after 200 seconds of the irradiation; and then
irradiating the porogen-removed dielectric film with second UV light having a second wavelength which is shorter than the first wavelength, thereby increasing mechanical strength of the dielectric film.

2. The method according to claim 1, wherein the first wavelength is in the range of 200 nm to 300 nm.

3. The method according to claim 1, wherein the second wavelength is 200 nm or lower.

4. The method according to claim 1, wherein the porogen is a pore-generating precursor gas containing C and H.

5. The method according to claim 4, wherein the porogen is a hydrocarbon-containing gas.

6. (canceled)

7. The method according to claim 1, wherein the initial dielectric film has an initial dielectric constant, the porogen removed dielectric film has a first dielectric constant, and the mechanical strength increased dielectric film has a second dielectric film, wherein the first dielectric constant is at least 10% lower than the initial dielectric constant, and the second dielectric constant is nearly the same as the first dielectric constant.

8. The method according to claim 1, further comprising determining an irradiation time of the first UV light based on a refractive index of a dielectric film equivalent to the initial dielectric film, wherein the irradiation time is such that the refractive index reaches substantially or nearly a minimum value.

9. The method according to claim 1, wherein the fist UV light is light emitted from a high-pressure mercury lamp, and the second UV light is emitted from an Xenon excimer lamp.

10. The method according to claim 1, wherein the initial dielectric film except the porogen is constituted by Si, C, O, and H.

11. The method according to claim 1, wherein the initial dielectric film has a thickness of 100 nm to 500 nm.

12. The method according to claim 1, wherein the initial dielectric film has an elastic modulus of 3 GPa to 4 GPa, and the mechanical strength-increased dielectric film has an elastic modulus of 5 GPa or higher.

13. The method according to claim 1, wherein the step of providing the initial dielectric film comprises forming the initial dielectric film on a substrate by plasma CVD.
